(19) United States
(12) Patent Application Publication
(10) Pub. No.: US 2013/0032777 A1
(43) Pub. Date: Feb. 7, 2013

(54) Semiconductor Device and Manufacturing Method thereof

(71) Applicants: Haizhou Yin, Poughkeepsie, NY (US); Zhijiong Luo, Poughkeepsie, NY (US); Huilong Zhu, Poughkeepsie, NY (US)

(72) Inventors: Haizhou Yin, Poughkeepsie, NY (US); Zhijiong Luo, Poughkeepsie, NY (US); Huilong Zhu, Poughkeepsie, NY (US)

(21) Appl. No.: 13/376,237

(22) PCT Filed: Aug. 5, 2011
(86) PCT No.: PCT/CN11/01292

§ 371 Date: Dec. 5, 2011

(30) Foreign Application Priority Data
Sep. 18, 2011 (CN) 201110066371.5

(51) Int. Cl. H01L 29/06; H01L 21/20; B82Y 99/00; B82Y 40/00

(52) U.S. Cl. 257/9; 438/479; 438/482; 438/488; 438/478; 257/E29.005; 257/E21.09; 977/742; 977/842

(57) ABSTRACT

The present invention discloses a semiconductor device and a manufacturing method thereof. The method comprises the steps of providing a substrate on which a graphene layer or carbon nanotube layer is formed; exposing part of the graphene layer or carbon nanotube layer after forming a gate structure on the graphene layer or carbon nanotube layer, wherein the gate structure comprises a gate stack, a spacer and a cap layer, the cap layer is located on the gate stack, and the spacer surrounds the gate stack and the cap layer; epitaxially growing a semiconductor layer on the exposed graphene layer or carbon nanotube layer; and forming a metal contact layer on the semiconductor layer. In the present invention, the semiconductor layer is formed on the graphene layer or carbon nanotube layer, and then the metal contact layer is formed on the semiconductor layer, instead of forming the metal contact layer directly from the graphene layer or carbon nanotube layer. This facilitates to form the self-aligned source and drain contact plugs.

### CROSS-REFERENCE TO RELATED APPLICATION

This application is a National Stage application of, and claims priority to, PCT Application No. PCT/CN2011/001292, filed on Aug. 5, 2011, entitled “Semiconductor Device and Manufacturing Method thereof”, which claimed priority to Chinese Application No. 201110066371.6, filed on Mar. 18, 2011. Both the PCT Application and Chinese Application are incorporated herein by reference in their entireties.

### FIELD OF THE INVENTION

The present invention relates to the field of semiconductor fabrication, and in particular, to a semiconductor device and a manufacturing method thereof.

### BACKGROUND OF THE INVENTION

Since its discovery, graphene has been the focus of study of research teams all over the world. It is a new form of carbon, and owing to a series of unique electrical and physical properties, it has become an ideal material for constructing nanometer electronic devices. However, graphene has a structure of single atomic layer, so it is difficult to perform an ion implantation doping thereto to form the self-aligned source and drain contact plugs of the device thereon.

### SUMMARY OF THE INVENTION

To solve the above-mentioned problem, the present invention provides a method of manufacturing a semiconductor device, which comprises: providing a substrate on which a graphene layer or carbon nanotube layer is formed; exposing part of said graphene layer or carbon nanotube layer after forming a gate structure on said graphene layer or carbon nanotube layer, wherein the gate structure comprises a gate stack, a spacer and a cap layer, the cap layer is located on the gate stack, and the spacer surrounds the gate stack and the cap layer; epitaxially growing a semiconductor layer on the exposed graphene layer or carbon nanotube layer; and forming a metal contact layer on the semiconductor layer.

In addition, the present invention provides a semiconductor device, which comprises: a substrate; a graphene layer or carbon nanotube layer, which is formed on the substrate; a gate structure formed on the graphene layer or carbon nanotube layer, wherein part of the graphene layer or carbon nanotube layer is exposed; a metal contact layer surrounding the gate structure and located on the exposed graphene layer or carbon nanotube layer.

With the method of manufacturing the semiconductor device as provided by the present invention, the semiconductor layer is formed on the graphene layer or carbon nanotube layer, and then the metal contact layer is formed on the semiconductor layer, instead of forming the metal contact layer directly from the graphene layer or carbon nanotube layer. This facilitates to form the self-aligned source and drain contact plugs.

### BRIEF DESCRIPTION OF THE DRAWINGS

FIG. 1 is a flow chart of an embodiment of the method of manufacturing the semiconductor device according to the present invention;

FIGS. 2-4 are cross-sectional views of the respective intermediate structures in the embodiment of the method of manufacturing the semiconductor device provided by the present invention.

### DETAILED DESCRIPTION OF THE PREFERRED EMBODIMENTS

The embodiments described below with reference to the drawings are exemplary, which are only for illustrating the present invention instead of limiting the present invention. The following disclosure provides a plurality of different embodiments or examples to achieve different structures of the present invention. To simplify the disclosure of the present invention, descriptions of the components and arrangements of specific examples are given below. Of course, they are only illustrative and not intended to limit the present invention. Moreover, in the present invention, reference numbers and/or letters may be repeated in different embodiments. Such repetition is for the purposes of simplification and clearness, and does not denote the relationship between respective embodiments and/or arrangements being discussed. In addition, the present invention provides various examples for specific process and materials. However, it is obvious for a person of ordinary skill in the art that other process and/or materials may alternatively be utilized. Furthermore, the following structure in which a first object is “on” a second object may include an embodiment in which the first object and the second object are formed to be in direct contact with each other, and may also include an embodiment in which another object is formed between the first object and the second object such that the first and second objects might not be in direct contact with each other.

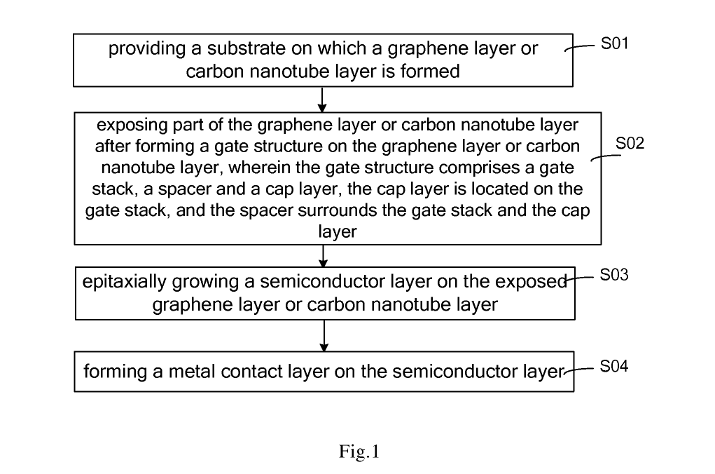

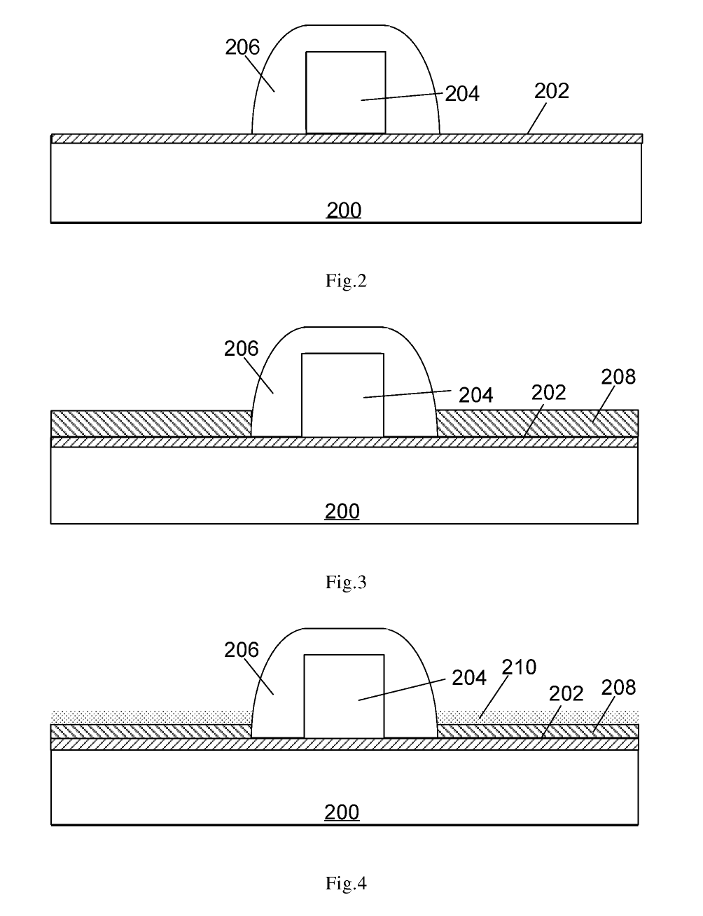

Referring to FIG. 1, a substrate is provided in step S01. With reference to FIG. 2, in one embodiment, a substrate 200 comprises one of silicon substrate (for example a wafer), silicon carbide, bulk silicon, and doped or un-doped silica glass, or any combination thereof. In other embodiments, the substrate 200 may also comprise other basic semiconductor or compound semiconductor, for example, Ge, GeSi, GaAs, InP, or diamond, etc. According to design specifications known in the prior art (for example, a p-type substrate or an n-type substrate), the substrate 200 may comprise various kinds of doping configurations. Further, the substrate 200 may alternatively comprise an epitaxial layer such that it may be manipulated under stress so as to enhance the performance, and may comprise a silicon-on-insulator (SOI) structure.

A graphene layer or carbon nanotube layer 202 is formed on the substrate 200, as shown in FIG. 2. The graphene layer or carbon nanotube layer 202 comprising a single-layer graphene material or a multiple-layer graphene material may be formed by, for example, CVD, thermal decomposition, or micro-mechanical stripping, and bonding transfer thereof, or other appropriate techniques.

In step S02, a gate structure is formed on the graphene layer or carbon nanotube layer. In one embodiment of the present invention, referring to FIG. 2, the gate structure comprises a gate stack 204, a spacer 206, and a cap layer. The spacer 206 may be an insulating material and may comprise a single-layer or multiple-layer structure; when it is a multiple-layer structure, the materials of adjacent two layers therein may be different. The cap layer may be an insulating material, and the material of the cap layer may be the same as the material of the spacer 206. The cap layer is located on the gate stack 204, and the spacer 206 surrounds the gate stack 204 and the cap layer. In one embodiment, the gate stack 204 may use metals, doped or undoped polysilicon, doped or undoped amorphous silicon, and doped or undoped silica glass to carry the cap layer. Herein, the gate stack 204 may also be a pseudo-gate stack, and may comprises a gate dielectric layer (e.g. silicon oxide or high-k dielectric material) and a gate/pseudo-gate (e.g. metals, doped or undoped polysilicon, doped or undoped amorphous silicon, and doped or undoped silica glass), or may comprise only a gate/pseudo-gate. Those skilled in the art may make a selection flexibly according to the need of the process, while the inventors only focus on teaching the influence to the implementation of the solution by the selection of the material of the gate stack 204 herein.

After forming the gate structure on the graphene layer or carbon nanotube layer, part of the graphene layer or carbon nanotube layer is exposed.

In step S03, a semiconductor layer 208 is epitaxially grown on the exposed graphene layer or carbon nanotube layer 202. The material of the semiconductor layer may be one of doped or undoped polysilicon, doped or undoped amorphous silicon, and doped or undoped monocrystaline silicon. In other embodiments, the material of the semiconductor layer may also be doped or undoped germanium or doped or undoped silicon germanium. As shown in FIG. 3, the semiconductor layer 208 may be formed on the exposed graphene layer or carbon nanotube layer 202 by means of an epitaxial growth process, namely, the semiconductor layer 208 is formed in a self-aligned manner, and then when the source and drain regions of the device are formed by using the semiconductor layer 208, the source and drain regions are formed in a self-aligned manner.

In one embodiment, the material of the semiconductor layer is doped or undoped polysilicon, doped or undoped amorphous silicon, or doped or undoped monocrystaline silicon.

In step S04, a metal contact layer 210 is formed on the semiconductor layer. The metal contact layer 210 may be formed by the conventional self-alignment process. Specifically, a metal layer is formed first on the semiconductor layer, which is of the material of Ti, Ni, Co, or other metal materials. Then a high temperature annealing is performed to make the metal layer react with the semiconductor layer 208 that is in contact therewith to form the metal contact layer 210. In this embodiment, the metal layer may react only with the surface layer of the semiconductor layer 208; in other embodiments, the metal layer may react with the entire semiconductor layer 208. Next, the un-reacted metal layer is removed to form the metal contact layer 210 in a self-aligned manner, as shown in FIG. 4.

Moreover, when the gate stack 204 carries the cap layer by doped or undoped polysilicon or amorphous silicon, forming the metal contact layer 210 on the semiconductor layer 208 comprises removing the cap layer first to expose the gate stack 204; then forming the metal contact layer 210 on the semiconductor layer 208 and on the gate stack 204. At this time, after an expitaxial growth of the semiconductor layer 208, the cap layer is removed, which facilitates to keep the appearance of the gate stack 204 and to reduce the number of steps needed for forming the metal contact layer 210 on the gate stack 204, thereby simplifying the process.

The present invention also provides a semiconductor device, which comprises: a substrate; a graphene layer or carbon nanotube layer formed on the substrate; a gate structure formed on the graphene layer or carbon nanotube layer and exposing part of the graphene layer or carbon nanotube layer, the gate structure comprising a gate stack and a spacer; and a metal contact layer formed on the graphene layer or carbon nanotube layer 202 on both sides of the gate structure.

In other embodiments, the semiconductor device may further comprises a semiconductor layer sandwiched between the metal contact layer and the graphene layer or carbon nanotube layer.

The graphene layer or carbon nanotube layer may comprise a single-layer or multiple-layer structure. The composition, material and forming method of the components in the embodiments of the semiconductor device can be the same as those described in the above embodiment of the method of manufacturing the semiconductor device, so they will not be repeated here.

While the exemplary embodiments and the advantages thereof have been described in details, it shall be understood that various changes, substitutions and modifications can be made to these embodiments without departing from the spirit of the present invention and the protection scope defined in the appended claims. As for other examples, it shall be understood by those skilled in the art that the order of the process steps may be changed without changing the protection scope of the present invention.

In addition, the scope to which the present invention is applied is not limited to the process, mechanism, manufacture, material composition, means, methods and steps described in the specific embodiments in the specification. Those skilled in the art would readily appreciate from the disclosure of the present invention that the process, mechanism, manufacture, material composition, means, methods or steps currently existing or to be developed in future, which perform substantially the same functions or achieve substantially the same as that in the corresponding embodiments described in the present invention, may be applied according to the teaching of the present invention. Therefore, the appended claims intend to include said process, mechanism, manufacture, material composition, means, methods or steps in the protection scope thereof.

What is claimed is:

1. A method of manufacturing a semiconductor device, comprising:
providing a substrate on which a graphene layer or carbon nanotube layer is formed;
exposing part of said graphene layer or carbon nanotube layer after forming a gate structure on said graphene layer or carbon nanotube layer, wherein the gate structure comprises a gate stack, a spacer and a cap layer, the cap layer is located on the gate stack, and the spacer surrounds the gate stack and the cap layer;
epitaxially growing a semiconductor layer on the exposed graphene layer or carbon nanotube layer; and
forming a metal contact layer on the semiconductor layer.

2. The method according to claim 1, wherein the substrate is one of silicon carbide, bulk silicon and doped or un-doped silica glass, or any combination thereof.

3. The method according to claim 1, wherein the gate stack carries the cap layer by means of metals, doped or undoped polysilicon, amorphous silicon, or silica glass.

4. The method according to claim 1, wherein when the gate stack carries the cap layer by means of a doped or undoped polysilicon or an amorphous silicon, forming the metal contact layer on the semiconductor layer comprises:
removing the cap layer to expose the gate stack; and
forming the metal contact layer on the semiconductor layer and on the gate stack.

5. The method according to claim 1, wherein forming the metal contact layer on the semiconductor layer comprises:
forming a metal layer on the semiconductor layer;
performing an annealing process to make the metal layer react with the semiconductor layer so as to form the metal contact layer; and
remove the un-reacted metal layer.

6. The method according to claim 1, wherein the material of the semiconductor layer is one of doped or undoped polysilicon, amorphous silicon, monocrystaline silicon, germanium and silicon germanium, or any combination thereof.

7. A semiconductor device, comprising:
a substrate;
a graphene layer or carbon nanotube layer formed on the substrate;
a gate structure formed on the graphene layer or carbon nanotube layer, wherein part of the graphene layer or carbon nanotube layer is exposed;
a metal contact layer surrounding the gate structure and located on the exposed graphene layer or carbon nanotube layer.

8. The semiconductor device according to claim 7, wherein the semiconductor device further comprises a semiconductor layer sandwiched between the metal contact layer and the graphene layer or carbon nanotube layer.

9. The semiconductor device according to claim 8, wherein the material of the semiconductor layer is one of doped or undoped polysilicon, amorphous silicon, monocrystaline silicon, germanium and silicon germanium, or any combination thereof.

10. The semiconductor device according to claim 7, wherein the substrate is one of silicon carbide, bulk silicon and doped or un-doped silica glass, or any combination thereof.
